(19) United States
(12) Patent Application Publication
(10) Pub. No.: US 2014/0119491 A1
(43) Pub. Date: May 1, 2014

(54) SHIFT REGISTER AND METHOD FOR DRIVING THE SAME, GATE DRIVING DEVICE AND DISPLAY DEVICE

(71) Applicant: BOE TECHNOLOGY GROUP CO., LTD., Beijing (CN)

(72) Inventor: Yaohu Liu, Beijing (CN)

(73) Assignee: BOE TECHNOLOGY GROUP CO., LTD., Beijing (CN)

(21) Appl. No.: 14/064,295

(22) Filed: Oct. 28, 2013

(30) Foreign Application Priority Data
Oct. 29, 2012 (CN) 201210421295.0

(51) Int. Cl. G11C 19/28

(52) U.S. Cl. CPC G11C 19/28
USPC 377/64

(57) ABSTRACT

The embodiments of the present invention provide a shift register and a method for driving the same, a gate driving device and a display device. A charging unit, a pull-up unit, a pull-down unit, a gate signal input terminal, a DC low level signal input terminal, a gate signal output terminal and a first, a second, a third, a fourth clock signal input terminals are arranged in the shift register, so that the gate driving structure is simplified and the power consumption of the gate driving is reduced.

### CROSS-REFERENCE TO RELATED APPLICATIONS

The present application claims priority to and incorporates by reference the entire contents of Chinese priority document 201210421295.0, filed in China on Oct. 29, 2012.

### TECHNICAL FIELD

The embodiments of the present invention relate to a display field, and more particularly to a shift register and a method for driving the same, a gate driving device and a display device.

### BACKGROUND

In a flat panel display, a fundamental principle for displaying a frame of picture is that a source driver outputs data signals to a data line and a gate driver outputs a square waveform with a certain width to a gate line sequentially from top to bottom so as to enable the gate.

In the conventional producing process, a gate driving IC and a source driving IC are bonded on a glass panel by a COG (Chip On Glass) process.

However, in the gate driving structure of the prior art, the output of the Nth line is commonly used as a reset signal for the N-1th line, which results in that the gate driving structure is complicated and power consumption is high.

### SUMMARY

The present invention aims to provide a shift register and a method for driving the same, a gate driving device and a display device, so that the gate driving structure can be simplified and the power consumption of the gate driving can be reduced.

In order to achieve the above objects, the embodiments of the present invention provide the solutions as follows.

An embodiment of the present invention provides a shift register may comprise a charging unit, a pull-up unit, a pull-down unit, a gate signal input terminal, a DC low level signal input terminal, a first clock signal input terminal, a second clock signal input terminal, a third clock signal input terminal, a fourth clock signal input terminal and a gate signal output terminal.

The charging unit may be coupled to the gate signal input terminal, the first clock signal input terminal, the pull-up unit and the pull-down unit respectively so as to control a potential of a pull-up node as a high level during a charging phase;

the pull-up unit may be coupled to the charging unit, the pull-down unit, the second clock signal input terminal and the gate signal output terminal respectively so as to output a high level signal input by the second clock signal input terminal to the gate signal output terminal during an output phase; and

the pull-down unit may be coupled to the charging unit, the pull-up unit, the DC low level signal input terminal, the third clock signal input terminal and the fourth clock signal input terminal respectively so as to control potentials of the pull-up node and the gate signal output terminal as a low level during a reset phase and a reset maintaining phase.

Preferably, the charging unit may comprise a first thin film transistor. The source of the first thin film transistor may be coupled to the gate signal input terminal, the gate of the first thin film transistor may be coupled to the first clock signal terminal, and the drain of the first thin film transistor may be coupled to the pull-up unit and the pull-down unit respectively via the pull-up node.

Preferably, the charging unit may comprise a first thin film transistor and a second thin film transistor. The source of the first thin film transistor may be coupled to the gate signal input terminal, the gate of the first thin film transistor may be coupled to the first clock signal input terminal, and the drain of the first thin film transistor may be coupled to the pull-up unit and the pull-down unit respectively via the pull-up node; and

The source and the gate of the second thin film transistor may be coupled to the gate signal input terminal, the drain of the second thin film transistor may be coupled to the pull-up unit and the pull-down unit respectively via the pull-up node.

Preferably, the pull-up unit may comprise a third thin film transistor. The source of the third thin film transistor may be coupled to the second clock signal input terminal, the gate of the third thin film transistor may be coupled to the charging unit and the pull-down unit respectively via the pull-up node, and the drain of the third thin film transistor may be coupled to the gate signal output terminal and the pull-down unit respectively.

Preferably, the pull up unit may further comprise a storage capacitor. A first terminal of the storage capacitor may be coupled to the gate of the third thin film transistor, the pull up unit and the pull-down unit via the pull-up node, while a second terminal of the storage capacitor may be coupled to the drain of the third thin film transistor, the gate signal output terminal and the pull-down unit respectively.

Preferably, the pull-down unit may comprise a first pull-down unit and a second pull-down unit. The first pull-down unit may be coupled to the third clock signal input terminal and the DC low level signal input terminal respectively so as to control potentials of the pull-up node and the gate signal output terminal as a low level during a reset phase; and

the second pull-down unit may be coupled to the fourth clock signal input terminal and the DC low level signal input terminal respectively so as to control potentials of the pull-up node and the gate signal output terminal as a low level during a reset maintaining phase.

Preferably, the first pull-down unit may comprise a fourth thin film transistor and a fifth thin film transistor. The source of the fourth thin film transistor may be coupled to the charging unit and the pull-up unit respectively via the pull-up node, the gate of the fourth thin film transistor may be coupled to the third clock signal input terminal, the drain of the fourth thin film transistor may be coupled to the DC low level signal input terminal; and

the source of the fifth thin film transistor may be coupled to the pull-up unit and the gate signal output terminal respectively via the pull-up node, the gate of the fifth thin film transistor may be coupled to the third clock signal input terminal, and the drain of the fifth thin film transistor may be coupled to the DC low level signal input terminal.

Preferably, the second pull-down unit may comprise a sixth thin film transistor and a seventh thin film transistor.

The source of the sixth thin film transistor may be coupled to the pull-up unit and the gate signal output terminal respectively, the gate of the sixth thin film transistor may be coupled to the fourth clock signal input terminal, and the drain of the sixth thin film transistor may be coupled to the DC low level signal input terminal; and

the source of the seventh thin film transistor may be coupled to the charging unit and the pull-up unit respectively via the pull-up node, the gate of the seventh thin film transistor may be coupled to the fourth clock signal input terminal, and the drain of the seventh thin film transistor may be coupled to the DC low level signal input terminal.

Preferably, the shift register may further comprise a DC high level signal input terminal.

Preferably, the first pull-down unit may comprise a fourth thin film transistor, a fifth thin film transistor, an eighth thin film transistor and a tenth thin film transistor.

The source of the fourth thin film transistor may be coupled to the charging unit, the pull-up unit and the gate of the tenth thin film transistor respectively via the pull-up node, the gate of the fourth thin film transistor may be coupled to the drain of the eighth thin film transistor and the source of the tenth thin film transistor respectively, and the drain of the fourth thin film transistor may be coupled to the DC low level signal input terminal;

the source of the fifth thin film transistor may be coupled to the pull-up unit and the gate signal output terminal respectively, the gate of the fifth thin film transistor may be coupled to the drain of the eighth thin film transistor and the source of the tenth thin film transistor respectively, and the drain of the fifth thin film transistor may be coupled to the DC low level signal input terminal;

the source of the eighth thin film transistor may be coupled to the DC high level signal input terminal, the gate of the eighth thin film transistor may be coupled to the third clock signal input terminal, and the drain of the eighth thin film transistor may be coupled to the gate of the fourth thin film transistor, the gate of the fifth thin film transistor and the source of the tenth thin film transistor respectively; and

the drain of the tenth thin film transistor may be coupled to the DC low level signal input terminal.

Preferably, the second pull-down unit may comprise a sixth thin film transistor, a seventh thin film transistor, a ninth thin film transistor and an eleventh thin film transistor.

The source of the sixth thin film transistor may be coupled to the pull-up unit and the gate signal output terminal respectively, the gate of the sixth thin film transistor may be coupled to the drain of the ninth thin film transistor and the source of the eleventh thin film transistor respectively, the drain of the sixth thin film transistor may be coupled to the DC low level signal input terminal;

the source of the seventh thin film transistor may be coupled to the charging unit, the pull-up unit and the gate of the eleventh thin film transistor respectively via the pull-up node, the gate of the seventh thin film transistor may be coupled to the drain of the ninth thin film transistor and the source of the eleventh thin film transistor respectively, the drain of the seventh thin film transistor may be coupled to the DC low level signal input terminal;

the source of the ninth thin film transistor may be coupled to the DC high level signal input terminal, the gate of the ninth thin film transistor may be coupled to the fourth clock signal input terminal, the drain of the ninth thin film transistor may be coupled to the gate of the sixth thin film transistor, the gate of the seventh thin film transistor and the source of the eleventh thin film transistor respectively; and

the drain of the eleventh thin film transistor may be coupled to the DC low level signal input terminal.

The embodiment of the present invention may further provide a method for driving a shift register, which may be applied in the above shift register according to the embodiments of the present invention. The method may comprise:

during a charging phase, a gate signal input terminal inputting a gate signal, a first clock signal input terminal inputting a high level, a second, a third, a fourth clock signal input terminals inputting a low level, a charging unit controlling a potential of a pull-up node as a high level and starting to charge;

during an output phase, the gate signal input terminal completing inputting, the first, the third and the fourth clock signal input terminals inputting a low level, the second clock signal input terminal inputting a high level, a pull-up unit outputting the high level signal input by the second clock signal input terminal to a gate signal output terminal;

during a reset phase, the first, the second, the fourth clock signal input terminals inputting a low level, the third clock signal input terminal inputting a high level, a pull-down unit controlling potentials of a pull-up node and the gate signal output terminal as a low level; and

during a reset maintaining phase, the first, the second, the third clock signal input terminals inputting a low level, the fourth clock signal input terminal inputting a high level, the pull-down unit continuously controlling the potentials of the pull-up node and the gate signal output terminal as a low level.

The embodiment of the present invention may further provide a gate driving device, comprising multiple stages of shift registers according to the embodiment of the present invention; except for the last stage of shift registers, each gate signal output terminal of remaining stages of shift registers is coupled to a gate signal input terminal of the next stage of shift registers.

The embodiment of the present invention may provide a display device, comprising the gate driving device according to the embodiment of the present invention.

From the above description, the embodiments of the present invention may provide a shift register and a method for driving the same, a gate driving device and a display device. The shift register may comprise a charging unit, a pull-up unit, a pull-down unit, a gate signal input terminal, a DC low level signal input terminal, a first clock input terminal, a second clock signal input terminal, a third clock signal input terminal, a fourth clock signal input terminal and a gate signal output terminal. Further, the charging unit may be coupled to the gate signal input terminal, the first clock signal input terminal, the pull-up unit and the pull-down unit respectively so as to control a potential of a pull-up node as a high level during a charging phase; the pull-up unit may be coupled to the charging unit, the pull-down unit, the second clock signal input terminal and the gate signal output terminal respectively so as to output a high level signal input by the second clock signal input terminal to the gate signal output terminal during an output phase; the pull-down unit may be coupled to the charging unit, the pull-up unit, the DC low level signal input terminal, the third clock signal input terminal and the fourth clock signal input terminal respectively so as to control potentials of the pull-up node and the gate signal output terminal as a low level during a reset phase and a reset maintaining phase. Therefore, the gate driving structure can be simplified and the power consumption of the gate driving can be reduced.

### BRIEF DESCRIPTION OF THE DRAWINGS

The present invention will be more clearly understood from the description of preferred embodiments as set forth below, with reference to the accompanying drawings, wherein:

FIG. 1 is the first schematic circuit diagram of a shift register according to an embodiment of the present invention;

FIG. 2 is a schematic structure diagram of a charging unit according to an embodiment of the present invention;

FIG. 3 is the second schematic circuit diagram of a shift register according to an embodiment of the present invention;

FIG. 4 is a schematic structure diagram of a pull-up unit according to an embodiment of the present invention;

FIG. 5 is a schematic structure diagram of a pull-down unit according to an embodiment of the present invention;

FIG. 6 is a sequential chart of a shift register according to an embodiment of the present invention;

FIG. 7 is the third schematic circuit diagram of a shift register according to an embodiment of the present invention;

FIG. 8 is a schematic flowchart of a method for driving a shift register according to an embodiment of the present invention;

FIG. 9 is the first schematic structure diagram of a gate driving device according to an embodiment of the present invention;

FIG. 10 is the first sequential chart of a gate driving device according to an embodiment of the present invention;

FIG. 11 is the second schematic structure diagram of a gate driving device according to an embodiment of the present invention; and

FIG. 12 is the second sequential chart of a gate driving device according to an embodiment of the present invention.

### DETAILED DESCRIPTION

In order to clearly set forth the aim, technical solutions and advantages of embodiments of the present disclosure, the embodiments of the present disclosure are further described in conjunction with drawings and embodiments. The embodiments of the present invention are only used for illustration and explanation, and are not used to limit the present invention.

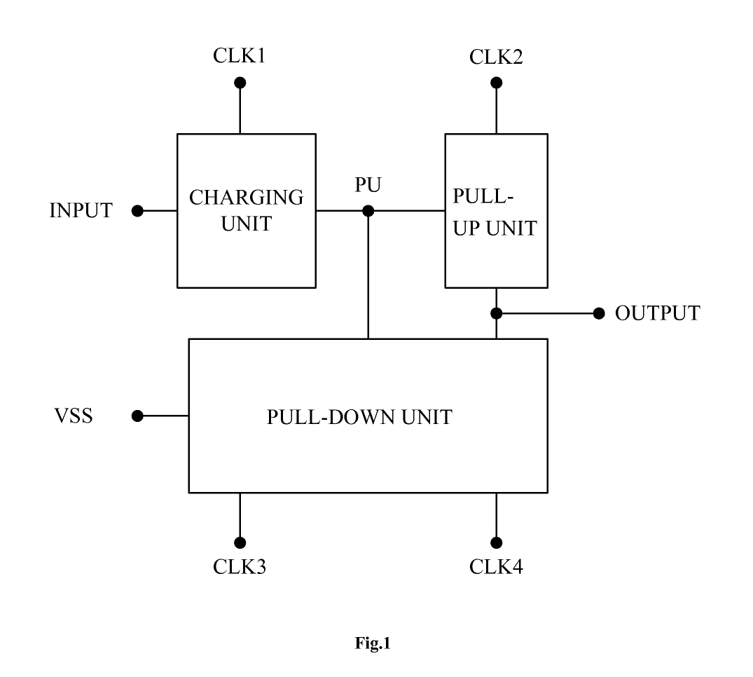

As shown in FIG. 1, an embodiment of the present invention provides a shift register which comprises:

A charging unit 11, a pull-up unit 12, a pull-down unit 13, a gate signal input terminal INPUT, a DC low level signal input terminal VSS, a first clock signal input terminal CLK1, a second clock signal input terminal CKL2, a third clock signal input terminal CLK3, a fourth clock signal input terminal CLK4 and a gate signal output terminal OUTPUT.

The charging unit 11 may be coupled to the gate signal input terminal INPUT, the first clock signal input terminal CLK1, the pull-up unit 12 and the pull-down unit 13 respectively so as to control a potential of a pull-up node PU as a high level during a charging phase.

The pull-up unit 12 may be coupled to the charging unit 11, the pull-down unit 13, the second clock signal input terminal CKL2 and the gate signal output terminal OUTPUT respectively so as to output a high level signal input by the second clock signal input terminal to the gate signal output terminal.

The pull-down unit 13 may be coupled to the charging unit 11, the pull-up unit 12, the DC low level signal input terminal VSS, the third clock signal input terminal CLK3 and the fourth clock signal input terminal CLK4 respectively so as to control potentials of the pull-up node PU and the gate signal output terminal OUTPUT as a low level during both a reset phase and a reset maintaining phase.

The shift register provided in the embodiment of the present invention may be a GOA (Gate Driver On Array) circuit. Since a structure having four clock signal input terminals is adopted, such structure can solve the problem for resetting signals, it is not necessary to use an output signal of a shift register in the next row as a reset signal in the shift register provided in the embodiment of the present invention, so that the gate driving structure can be simplified.

Furthermore, since the structure having four clock signal input terminals is adopted, the frequency thereof is decreased. According to the power calculation equation P=a*C*V̂2*F (where a is a power factor, C is a capacitance, V is a voltage and F is a frequency), when other parameters are constant, since the frequency is decreased, power of the shift register and power of the gate driving device can be relatively reduced.

The clock signals input by the four clock signal input terminals according to the embodiment of the present invention may be high level signals which are alternately input in a certain period. For example, a first clock signal, a second clock signal, a third clock signal and a fourth clock signal are high level signals that are input sequentially. In one embodiment, in the first phase, that is a charging phase, the gate signal input terminal inputs a gate signal, in the mean time, the first clock signal input terminal inputs a high level, while the second, the third and the fourth clock signal input terminal input a low level respectively. In the second phase, that is an output phase, the gate signal input terminal stops inputting, the first, the third and the fourth clock signal input terminals input a low level, while the second clock signal input terminal inputs a high level. In the third phase, that is a reset phase, the first, the second and the fourth clock signal input terminals input a low level and the third clock signal input terminal inputs a high level. Finally in the reset maintaining phase, the first, the second and the third clock signal input terminals input a low level and the fourth clock signal input terminal inputs a high level.

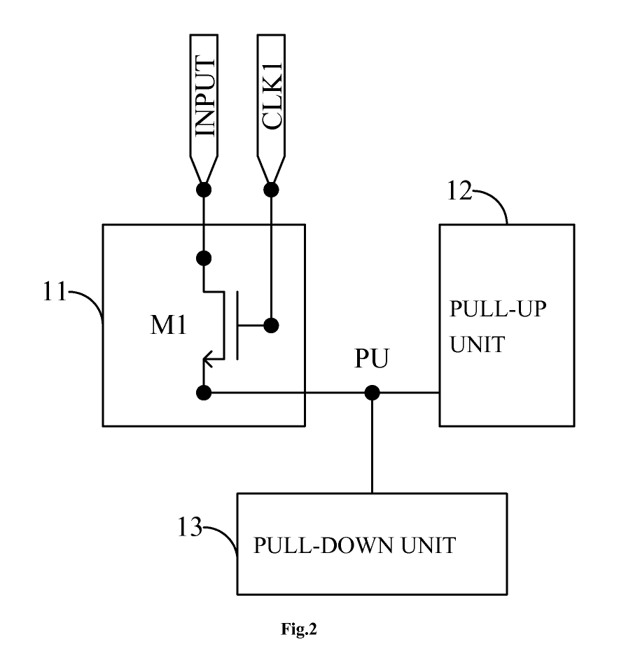

As shown in FIG. 2, the charging unit according to an embodiment of the present invention may comprise a first thin film transistor M1.

The source of the first thin film transistor M1 is coupled to the gate signal input terminal. The gate of the first thin film transistor M1 is coupled to the first clock signal terminal CLK1. The drain of the first thin film transistor M1 is coupled to the pull-up unit 12 and the pull-down unit 13 respectively via the pull-up node PU.

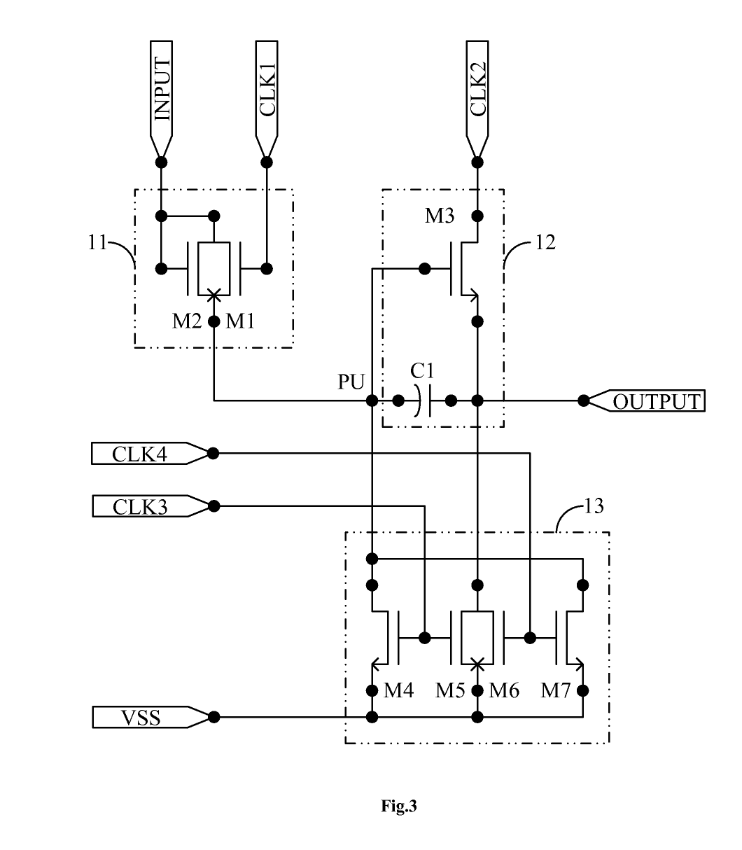

In another embodiment of the present invention, as shown in FIG. 3 (FIG. 3 shows a specific form of shift register according to an embodiment of the present invention), the charging unit 11 according to the embodiment of the present invention further comprises a second thin film transistor M2. That is, the charging unit comprises a first thin film transistor M1 and a second thin film transistor M2.

The source of the first thin film transistor M1 is coupled to the gate signal input terminal INPUT, the gate of the first thin film transistor M1 is coupled to the first clock signal input terminal CLK1, and the drain of the first thin film transistor M1 is coupled to the pull-up unit 12 and the pull-down unit 13 respectively via the pull-up node PU.

The source and the gate of the second thin film transistor M2 are coupled to the gate signal input terminal INPUT, the drain of the second thin film transistor M2 is coupled to the pull-up unit 12 and the pull-down unit 13 respectively via the pull-up node PU.

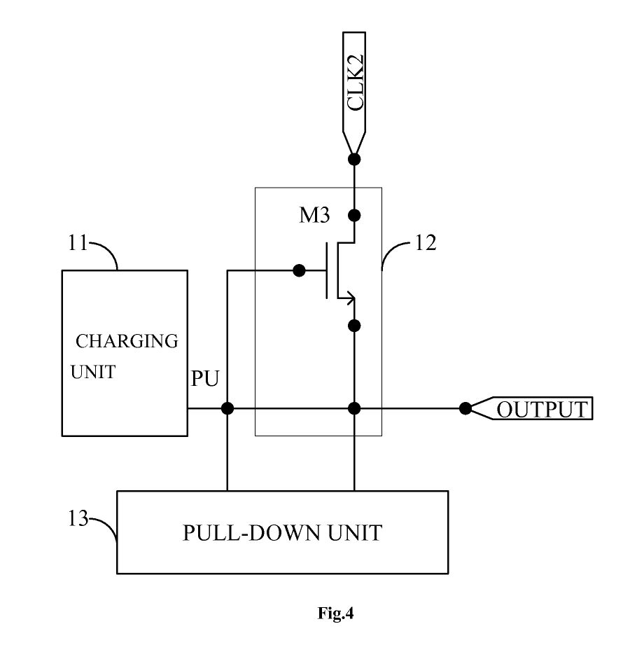

As shown in FIG. 4, the pull-up unit 12 according to the embodiment of the present invention comprises a third thin film transistor M3.

The source of the third thin film transistor M3 is coupled to the second clock signal input terminal CLK2, the gate of the third thin film transistor M3 is coupled to the charging unit 11 and the pull-down unit 13 respectively via the pull-up node PU, and the drain of the third thin film transistor M3 is coupled to the gate signal output terminal OUTPUT and the pull-down unit 13 respectively.

In one preferred embodiment, the pull-up unit 11 may further comprise a storage capacitor C1. As shown in FIG. 3, the first terminal of C1 (referring to the left terminal shown in FIG. 3) may connect the gate of the third thin film transistor M3, the charging unit 11 and the pull-down unit 13 via the pull-up node PU, the second terminal of C1 (referring to the right terminal shown in FIG. 3) is coupled to the gate signal output terminal OUTPUT and the pull-down unit 13.

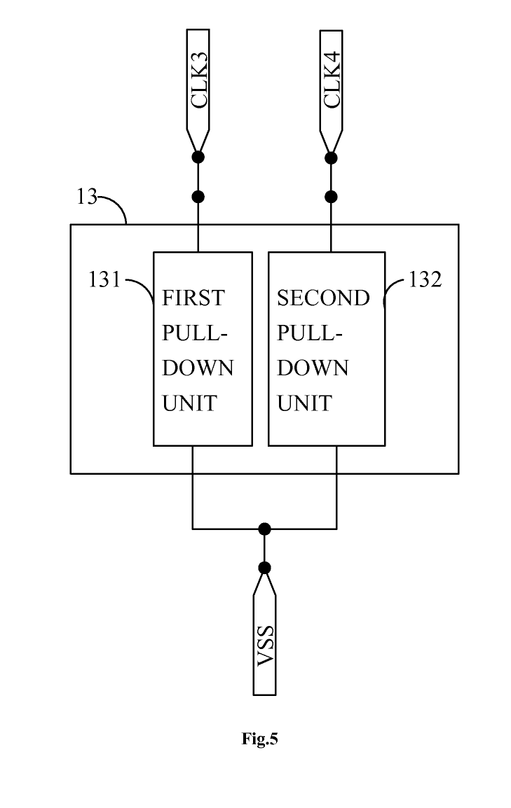

As shown in FIG. 5, the pull-down unit 13 according to the embodiment of the present invention may comprise a first pull-down unit 131 and a second pull-down unit 132.

The first pull-down unit 131 is coupled to the third clock signal input terminal CLK3 and the DC low level signal input terminal VSS respectively so as to control potentials of the pull-up node PU and the gate signal output terminal OUTPUT as a low level during a reset phase.

The second pull-down unit 132 is coupled to the fourth clock signal input terminal CLK4 and the DC low level signal input terminal VSS respectively so as to control potentials of the pull-up node PU and the gate signal output terminal OUTPUT as a low level during a reset maintaining phase.

In one preferred embodiment, as shown in FIG. 3, the first pull-down unit 131 (not shown in FIG. 3) may comprise a fourth thin film transistor M4 and a fifth thin film transistor M5.

The source of the fourth thin film transistor M4 is coupled to the charging unit 11 and the pull-up unit 12 respectively via the pull-up node PU. The gate of the fourth thin film transistor M4 is coupled to the third clock signal input terminal CLK3. The drain of the fourth thin film transistor M4 is coupled to the DC low level signal input terminal VSS.

The source of the fifth thin film transistor M5 is coupled to the pull-up unit 12 and the gate signal output terminal OUTPUT respectively via the pull-up node PU. The gate of the fifth thin film transistor M5 is coupled to the third clock signal input terminal CLK3. The drain of the fifth thin film transistor M5 is coupled to the DC low level signal input terminal VSS.

Similarly, in the preferred embodiment as shown in FIG. 3, the second pull-down unit 132 (not shown in FIG. 3) may comprise a sixth thin film transistor M6 and a seventh thin film transistor M7.

The source of the sixth thin film transistor M6 is coupled to the pull-up unit 12 and the gate signal input terminal INPUT respectively. The gate of the sixth thin film transistor M6 is coupled to the fourth clock signal input terminal CLK4. The drain of the sixth thin film transistor M6 is coupled to the DC low level signal input terminal VSS.

The source of the seventh thin film transistor M7 is coupled to the charging unit 11 and the pull-up unit 12 respectively via the pull-up node PU. The gate of the seventh thin film transistor M7 is coupled to the fourth clock signal input terminal CLK4. The drain of the seventh thin film transistor is coupled to the DC low level signal input terminal VSS.

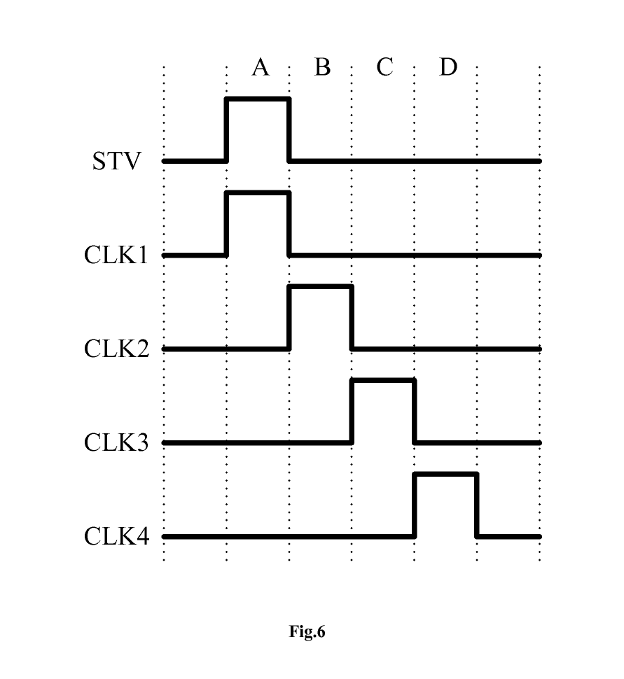

FIG. 6 shows a sequential chart of the shift register according to an embodiment of the present invention. STV is a start signal that is used as a gate input signal of the first stage of shift register. The gate signals output by output terminals OUTPUT of a previous stage of shift registers are used as a gate (INPUT) input signal for remaining stages (except for the first stage) of shift registers.

Based on the sequential chart shown in FIG. 6, the specific process of the shift register according to the embodiment of the present invention is as follows.

During a charging phase (that is phase A in FIG. 6), INPUT inputs STV, CLK1 inputs a high level (that is an input clock signal), CLK2, CLK3, CLK4 input a low level. At that time, M1 and M2 are turned on, e.g., in ON state and other thin film transistors (i.e., M3, M4, M5, M6 and M7) are in cut-off state, e.g., OFF state. The charging unit 11 controls the potential of the pull-up node as a high level, and the charging unit 11 starts to charge C1.

During an output phase (that is phase B in FIG. 6), INPUT stops inputting, CLK1, CLK3 and CLK4 input a low level. CLK2 inputs a high level so that M3 is in ON state (other thin film transistors are in cut-off state). The clock signal input from CLK2 pull the potential of the pull-up node PU high again by the coupling effect of M3. That is, the pull-up unit 12 controls the potential of the pull-up node PU as a high level. That is, the pull-up unit 12 controls the clock signal input from CLK2 so as to output it to the gate signal output terminal OUTPUT, and the gate signal output terminal OUTPUT outputs a high level, that is to output a gate signal.

During the reset phase (that is phase C in FIG. 6, the normal output of the gate signal output terminal OUTPUT completes), CLK1, CLK2 and CLK4 input a low level, CLK3 inputs a high level so that M4 and M5 are in ON state. Therefore, the pull-up node PU and the gate signal output terminal OUTPUT are in discharging state, that is, the pull down unit 13(specifically, may be the first pull-down unit 131) controls the potentials of the pull-up node PU and the gate signal output terminal OUTPUT as a low level. At this time, other thin film transistors are in cut-off state.

During reset maintaining phase (that is phase D in FIG. 6), CLK1, CLK2 and CLK3 input a low level, CLK4 inputs a high level, so that M6 and M7 are in On state (other thin film transistors are in cut-off state). Therefore, the pull-up node PU and the gate signal output terminal OUTPUT are kept as a low level, that is the pull-down unit 13 (specifically may be the second pull-down unit 132) continuously controls the potentials of the pull-up node PU and the gate signal output terminal OUTPUT as a low level during the reset maintaining phase.

In the embodiment of the present invention, since CLK3 and CLK4 input high levels respectively during the reset phase and the reset maintaining phase, M4, M5 and M6, M7 alternately turn on (that in being ON state). Therefore, the pull-up node PU and the gate signal output terminal OUTPUT are kept as a low level during the above two phases so as to remove noise.

The shift register having the structure shown in FIG. 3 according to the embodiment of the present invention has the advantage of occupying less area and being beneficial for a narrow frame design.

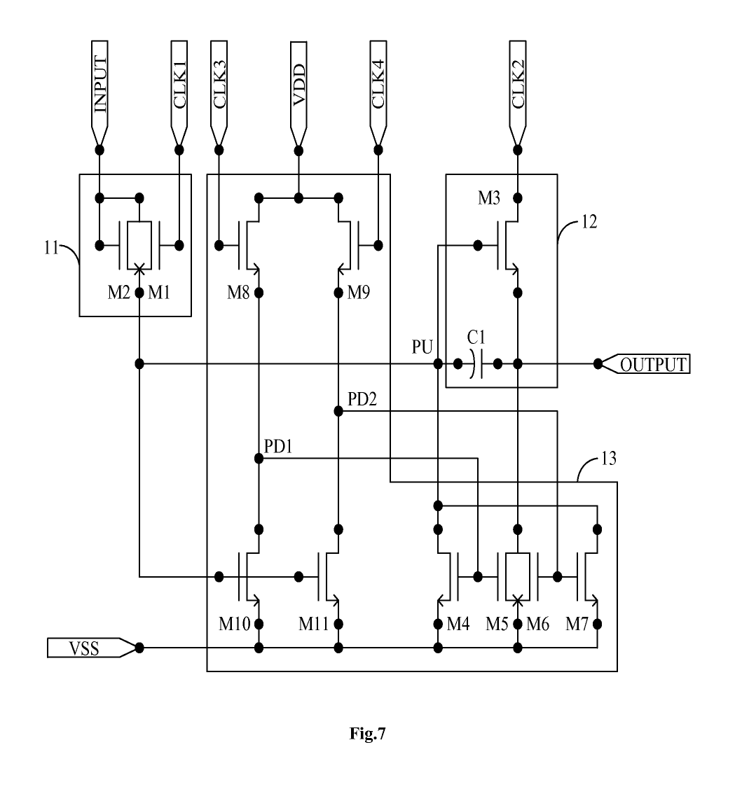

In another embodiment of the present invention, the shift register is shown in FIG. 7.

In the embodiment shown in FIG. 7, the shift register according to an embodiment of the present invention may further comprise a DC high level signal input terminal VDD.

In the shift register shown in FIG. 7, the circuit configurations of the charging unit 11 and the pull-up unit 12 are the same as that in the above shift register according to an embodiment of the present invention. However, the circuit configuration of the pull-down unit 13 has structural changes differing from that of the above embodiment.

In the embodiment of the present invention as shown in FIG. 7, the first pull-down unit 131 (not shown in figures) comprised in the pull-down unit 13 may comprise a fourth thin film transistor M4, a fifth thin film transistor M5, an eighth thin film transistor M8 and a tenth thin film transistor M10.

The source of the fourth thin film transistor M4 is coupled to the charging unit 11, the pull-up unit 12 and the gate of the tenth thin film transistor respectively via the pull-up node PU. The gate of the fourth thin film transistor M4 is coupled to the drain of the eighth thin film transistor M8 and the source of the tenth thin film transistor M10 respectively. The drain of the fourth thin film transistor M4 is coupled to the DC low level signal input terminal VSS.

The source of the fifth thin film transistor M5 is coupled to the pull-up unit 12 and the gate signal output terminal OUTPUT respectively. The gate of the fifth thin film transistor M5 is coupled to the drain of the eighth thin film transistor M8 and the source of the tenth thin film transistor M10 respectively. The drain of the fifth thin film transistor M5 is coupled to the DC low level signal input terminal VSS.

The source of the eighth thin film transistor M8 is coupled to the DC high level signal input terminal VDD. The gate of the eighth thin film transistor M8 is coupled to the third clock signal input terminal CLK3. The drain of the eighth thin film transistor M8 is coupled to the gate of the fourth thin film transistor M4, the gate of the fifth thin film transistor M5 and the source of the tenth thin film transistor M10 respectively.

The connection between the source and the gate of the tenth thin film transistor M10 has been illustrated and will not be repeated herein. The drain of M10 is coupled to the DC low level signal input terminal VSS.

In the embodiment shown in FIG. 7, the second pull-down unit 132 (not shown in figures) comprised in the pull-down unit 13 may comprise a sixth thin film transistor M6, a seventh thin film transistor M7, a ninth thin film transistor M9 and an eleventh thin film transistor M11.

The source of the sixth thin film transistor M6 is coupled to the pull-up unit 12 and the gate signal output terminal OUTPUT respectively. The gate of the sixth thin film transistor M6 is coupled to the drain of the ninth thin film transistor M9 and the source of the eleventh thin film transistor M11 respectively. The drain of the sixth thin film transistor M6 is coupled to the DC low level signal input terminal VSS.

The source of the seventh thin film transistor M7 is coupled to the charging unit 11, the pull-up unit 12 and the gate of the eleventh thin film transistor M11 respectively via the pull-up node PU. The gate of the seventh thin film transistor M7 is coupled to the drain of the ninth thin film transistor M9 and the source of the eleventh thin film transistor M11 respectively. The drain of the seventh thin film transistor M7 is coupled to the DC low level signal input terminal VSS.

The source of the ninth thin film transistor M9 is coupled to the DC high level signal input terminal VDD. The gate of the ninth thin film transistor M9 is coupled to the fourth clock signal input terminal CLK4. The drain of the ninth thin film transistor M9 is coupled to the gate of the sixth thin film transistor M6, the gate of the seventh thin film transistor M7 and the source of the eleventh thin film transistor M11 respectively.

The connection between the source and the gate of the eleventh thin film transistor M11 has been illustrated and will not be repeated herein. The drain of M11 is coupled to the DC low level signal input terminal VSS.

The shift register as shown in FIG. 7 according to an embodiment of the present invention may operate based on the sequential chart shown in FIG. 6. The specific process may be as follows.

During a charging phase, INPUT inputs STV, CLK1 inputs a high level, CLK2, CLK3, CLK4 input a low level. At that time, M1, M2, M10 and M11 are in ON state and other thin film transistors (M3-M9) are in cut-off state. The charging unit 11 controls the potential of the pull-up node as a high level, the charging unit 11 starts to charge C1. Since M10 and M11 are in ON state, the first pull-down node PD1 and the second pull-down node PD2 are in low level.

During the output phase, INPUT stops inputting, CLK1, CLK3 and CLK4 input a low level. CLK2 inputs a high level so that M3, M10 and M11 are in ON state. The clock signal input from CLK2 pull the potential of the pull-up node PU high again by the coupling effect of M3. That is, the pull-up unit 12 controls the potential of the pull-up node PU as a high level. The clock signal input from CLK2 outputs to the gate signal output terminal OUTPUT, and the gate signal output terminal OUTPUT outputs a high level. Since M10 and M11 are in ON state, the first pull-down node PD1 and the second pull-down node PD2 are in a low level.

During the reset phase, CLK1, CLK2 and CLK4 input a low level, CLK3 inputs a high level so that M8, M4 and M5 are in ON state. Therefore, the pull-up node PU and the gate signal output terminal OUTPUT are in discharging state, that is, the pull-down unit 13 (specifically, may be the first pull-down unit 131) controls the potentials of the pull-up node PU and the gate signal output terminal OUTPUT as a low level. At this time, other thin film transistors are in cut-off state.

During the reset maintaining phase, CLK1, CLK2 and CLK3 input a low level, CLK4 inputs a high level, so that M9, M6 and M7 are in ON state (other thin film transistors are in cut-off state). Therefore, the pull-up node PU and the gate signal output terminal OUTPUT are kept as a low level, that is the pull-down unit 13 (specifically may be the second pull-down unit 132) continuously controls the potentials of the pull-up node PU and the gate signal output terminal OUTPUT as a low level during the reset maintaining phase.

In the embodiment as shown in FIG. 7, during the reset phase and the reset maintaining phase, CLK3 and CLK4 input a high level respectively so that M8, M4, M5 and M9, M6, M7 alternately turn on. Therefore, the pull-up node PU and the gate signal output terminal OUTPUT are kept as a low level during the above two phases so as to remove noise alike.

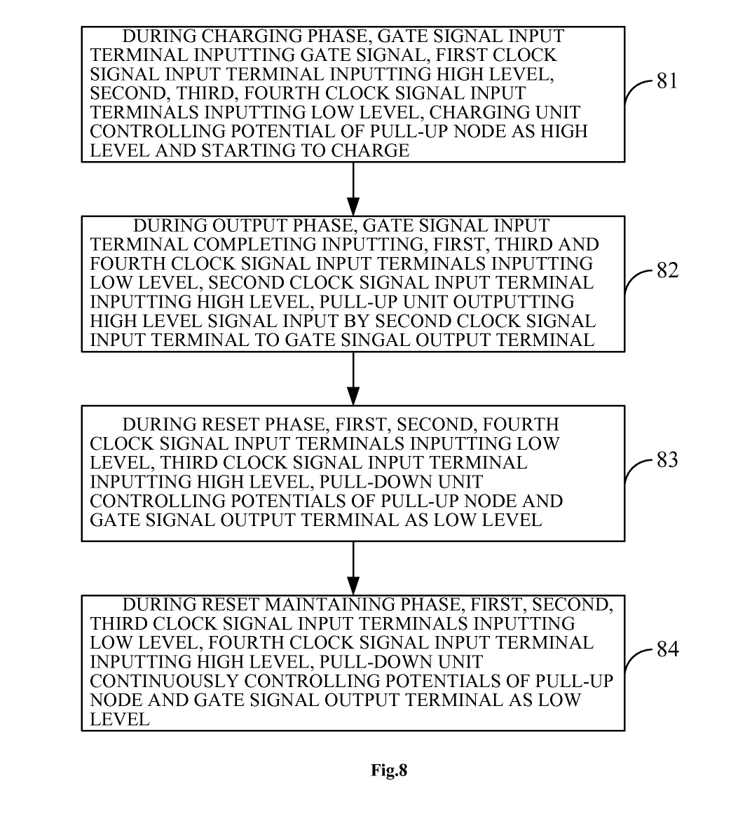

The embodiments of the present invention may further provide a method for driving a shift register. The method is used for the shift register according to the embodiments of the present invention. As shown in FIG. 8, the method may comprise:

Step 81, during a charging phase, a gate signal input terminal inputting a gate signal, a first clock signal input terminal inputting a high level, a second, a third, a fourth clock signal input terminals inputting a low level, a charging unit controlling a potential of the pull-up node as a high level and starting to charge;

Step 82, during an output phase, the gate signal input terminal completing inputting, the first, the third and the fourth clock signal input terminals inputting a low level, the second clock signal input terminal inputting a high level, the pull-up unit outputting the high level signal input by the second clock signal input terminal to a gate signal output terminal;

Step 83, during a reset phase, the first, the second, the fourth clock signal input terminals inputting a low level, the third clock signal input terminal inputting a high level, a pull-down unit controlling potentials of a pull-up node and the gate signal output terminal as a low level; and

Step 84, during a reset maintaining phase, the first, the second, the third clock signal input terminals inputting a low level, the fourth clock signal input terminal inputting a high level, the pull-down unit continuously controlling the potentials of the pull-up node and the gate signal output terminal as a low level.

The embodiment of the present invention may provide a gate driving device, comprising multiple stages of shift registers as shown in FIG. 1, 2 or 4 according to the embodiments of the present invention that are manufactured on a glass substrate of a liquid crystal display (LCD).

Specifically, except for the last stage of shift registers, each gate signal output terminal of remaining stages of shift registers may be coupled to a gate signal input terminal of the next stage of shift registers.

The gate driving device according to the embodiments of the present invention may be configured to have two kinds of structures: a one-side driving structure and a dual-side driving structure.

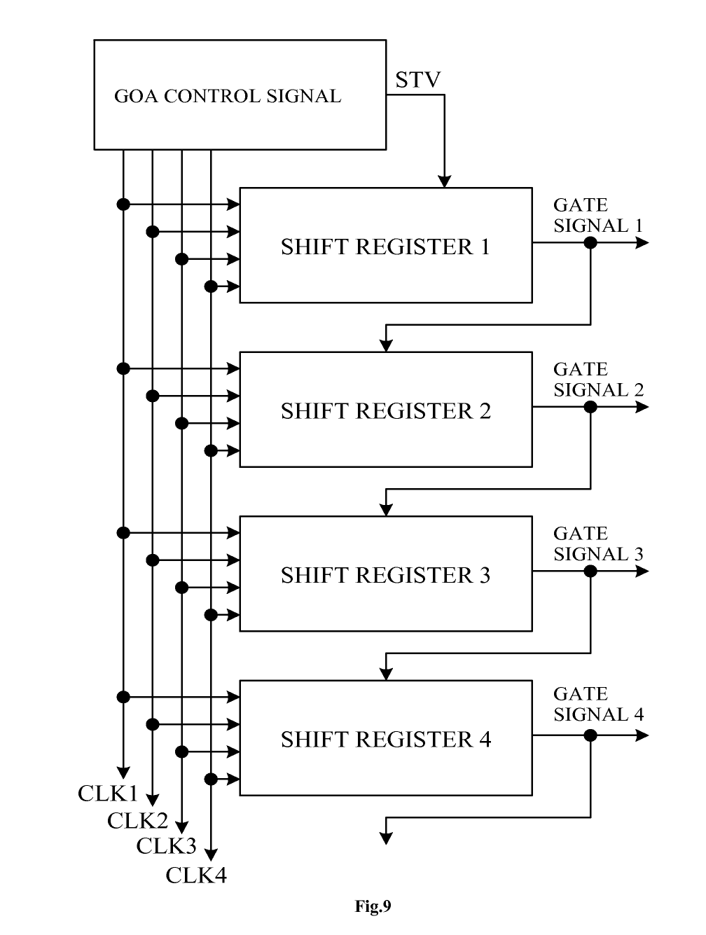

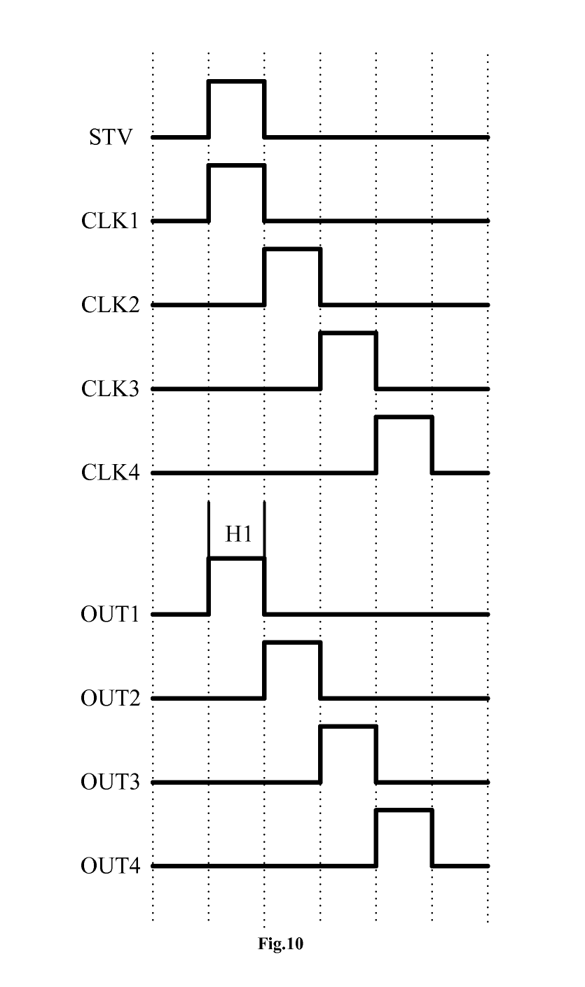

The schematics structure of the one-side driving is shown in FIG. 9 and the sequential chart thereof is shown in FIG. 10.

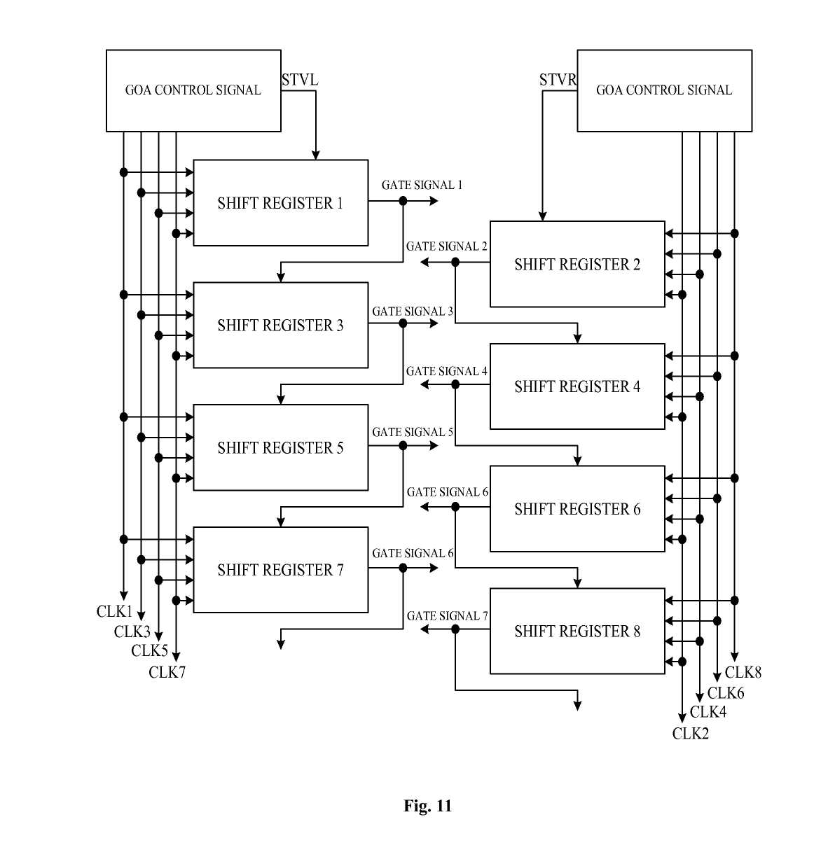

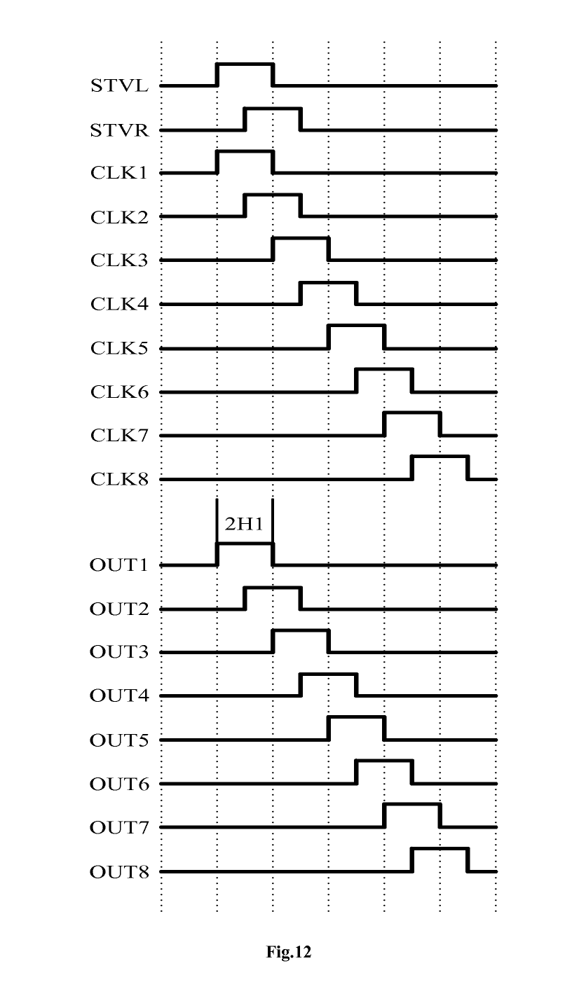

On the other hand, the schematic structure of the dual-side driving is shown in FIG. 11 and the sequential chart thereof is shown in FIG. 12.

Noted that, as shown in FIG. 10, H1=1/F/L, where F represents a picture refreshing rate, L represents a number of lines. For example, for a display having a resolution of 480*800, L represents 800. However, when a picture is displayed, there is a format issue. Therefore, L is slightly larger than 800 during a practical calculation. Of course, both F and L may take any other suitable values, which is not limited only to those disclosed by the embodiments of the present invention. As shown in FIG. 12, 2H1 represents twice as H1, and the filling-in part represents a valid time. Furthermore, as also shown in FIG. 12, STVL represents a gate input signal at the left side of the dual-side driving structure, and STVR represents a gate input signal at the right side of the dual-side driving structure.

Both the one-side driving structure and the dual-side driving structure as illustrated in the above embodiments of the present invention are also applicable to the shift registers as shown in FIG. 1, 2 or 4 according to the embodiments of the present invention. Further, these two driving structures may be also applied to other kinds of known or unknown shift registers, rather than being limited to those disclosed by the embodiments of the present invention.

The embodiment of the present invention may also provide a display device comprising a gate driving device according to the above embodiments of the present invention.

The display device may be a liquid crystal panel, a liquid crystal TV, a liquid crystal display, an OLED panel, an OLED display, a plasma display or an electrical paper and so on. However, the type of the display device is not limited to these. The gate driving device according to the above embodiments of the present invention may also be applied to other types of known or unknown display devices.

Further, the embodiment of the present invention may also provide an electronic product, which comprises any one of display devices disclosed by the embodiments of the present invention.

The shift register, the gate driving device and the display device according to the embodiments of the present invention are suitable for GOA circuit requirement under a low temperature poly-silicon (LTPS) process and are also suitable for a GOA circuit under an amorphous silicon process.

From the above description, the embodiments of the present invention provide a shift register and a method for driving the same, a gate driving device and a display device. A charging unit, a pull-up unit, a pull-down unit, a gate signal input terminal, a DC low level signal input terminal, a gate signal output terminal and a first, a second, a third, a fourth clock signal input terminals may be arranged within the shift register, so that the gate driving structure can be simplified and the power consumption of the gate driving can be reduced.

The above mentioned are only the embodiments of the present disclosure, which is not intended to limit the protection scope of the present disclosure. Thus any change, alternative, and modification within the spirit and principle of the embodiment of the present disclosure should belong to the scope of protected by the present disclosure.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A shift register, comprising a charging unit, a pull-up unit, a pull-down unit, a gate signal input terminal, a DC low level signal input terminal, a first clock signal input terminal, a second clock signal input terminal, a third clock signal input terminal, a fourth clock signal input terminal and a gate signal output terminal, wherein
the charging unit is coupled to the gate signal input terminal, the first clock signal input terminal, the pull-up unit and the pull-down unit respectively so as to control a potential of a pull-up node as a high level during a charging phase;
the pull-up unit is coupled to the charging unit, the pull-down unit, the second clock signal input terminal and the gate signal output terminal respectively so as to output a high level signal input by the second clock signal input terminal to the gate signal output terminal during an output phase; and
the pull-down unit is coupled to the charging unit, the pull-up unit, the DC low level signal input terminal, the third clock signal input terminal and the fourth clock signal input terminal respectively so as to control potentials of the pull-up node and the gate signal output terminal as a low level during a reset phase and a reset maintaining phase.

2. The shift register according to claim 1, wherein the charging unit comprises a first thin film transistor, wherein the source of the first thin film transistor is coupled to the gate signal input terminal, the gate of the first thin film transistor is coupled to the first clock signal input terminal, and the drain of the first thin film transistor is coupled to the pull-up unit and the pull-down unit respectively via the pull-up node.

3. The shift register according to claim 1, wherein the charging unit comprises a first thin film transistor and a second thin film transistor, wherein
the source of the first thin film transistor is coupled to the gate signal input terminal, the gate of the first thin film transistor is coupled to the first clock signal input terminal, and the drain of the first thin film transistor is coupled to the pull-up unit and the pull-down unit respectively via the pull-up node;
the source and the gate of the second thin film transistor are coupled to the gate signal input terminal, the drain of the second thin film transistor is coupled to the pull-up unit and the pull-down unit respectively via the pull-up node.

4. The shift register according to claim 1, wherein the pull-up unit comprises a third thin film transistor, wherein the source of the third thin film transistor is coupled to the second clock signal input terminal, the gate of the third thin film transistor is coupled to the charging unit and the pull-down unit respectively via the pull-up node, and the drain of the third thin film transistor is coupled to the gate signal output terminal and the pull-down unit respectively.

5. The shift register according to claim 4, wherein the pull up unit further comprises a storage capacitor, wherein a first terminal of the storage capacitor is coupled to the gate of the third thin film transistor, the pull up unit and the pull-down unit via the pull-up node, while a second terminal of the storage capacitor is coupled to the drain of the third thin film transistor, the gate signal output terminal and the pull-down unit respectively.

6. The shift register according to claim 1, wherein the pull-down unit comprises a first pull-down unit and a second pull-down unit, wherein
the first pull-down unit is coupled to the third clock signal input terminal and the DC low level signal input terminal respectively so as to control potentials of the pull-up node and the gate signal output terminal as a low level during the reset phase; and
the second pull-down unit is coupled to the fourth clock signal input terminal and the DC low level signal input terminal respectively so as to control potentials of the pull-up node and the gate signal output terminal as a low level during the reset maintaining phase.

7. The shift register according to claim 6, wherein the first pull-down unit comprises a fourth thin film transistor and a fifth thin film transistor, wherein
the source of the fourth thin film transistor is coupled to the charging unit and the pull-up unit respectively via the pull-up node, the gate of the fourth thin film transistor is coupled to the third clock signal input terminal, the drain of the fourth thin film transistor is coupled to the DC low level signal input terminal; and
the source of the fifth thin film transistor is coupled to the pull-up unit and the gate signal output terminal respectively via the pull-up node, the gate of the fifth thin film transistor is coupled to the third clock signal input terminal, and the drain of the fifth thin film transistor is coupled to the DC low level signal input terminal.

8. The shift register according to claim 6, wherein the second pull-down unit comprises a sixth thin film transistor and a seventh thin film transistor, wherein
the source of the sixth thin film transistor is coupled to the pull-up unit and the gate signal input terminal respectively, the gate of the sixth thin film transistor is coupled to the fourth clock signal input terminal and the drain of the sixth thin film transistor is coupled to the DC low level signal input terminal; and
the source of the seventh thin film transistor is coupled to the charging unit and the pull-up unit respectively via the pull-up node, the gate of the seventh thin film transistor is coupled to the fourth clock signal input terminal, and the drain of the seventh thin film transistor is coupled to the DC low level signal input terminal.

9. The shift register according to claim 6, wherein the shift register further comprises a DC high level signal input terminal.

10. The shift register according to claim 9, wherein the first pull-down unit comprises a fourth thin film transistor, a fifth thin film transistor, an eighth thin film transistor and a tenth thin film transistor, wherein
the source of the fourth thin film transistor is coupled to the charging unit, the pull-up unit and the gate of the tenth thin film transistor respectively via the pull-up node, the gate of the fourth thin film transistor is coupled to the drain of the eighth thin film transistor and the source of the tenth thin film transistor respectively, and the drain of the fourth thin film transistor is coupled to the DC low level signal input terminal;
the source of the fifth thin film transistor is coupled to the pull-up unit and the gate signal output terminal respectively, the gate of the fifth thin film transistor is coupled to the drain of the eighth thin film transistor and the source of the tenth thin film transistor respectively, and the drain of the fifth thin film transistor is coupled to the DC low level signal input terminal;
the source of the eighth thin film transistor is coupled to the DC high level signal input terminal, the gate of the eighth thin film transistor is coupled to the third clock signal input terminal, and the drain of the eighth thin film transistor is coupled to the gate of the fourth thin film transistor, the gate of the fifth thin film transistor and the source of the tenth thin film transistor respectively; and
the drain of the tenth thin film transistor is coupled to the DC low level signal input terminal.

11. The shift register according to claim 9, wherein the second pull-down unit comprises a sixth thin film transistor, a seventh thin film transistor, a ninth thin film transistor and an eleventh thin film transistor, wherein
the source of the sixth thin film transistor is coupled to the pull-up unit and the gate signal output terminal respectively, the gate of the sixth thin film transistor is coupled to the drain of the ninth thin film transistor and the source of the eleventh thin film transistor respectively, the drain of the sixth thin film transistor is coupled to the DC low level signal input terminal;
the source of the seventh thin film transistor is coupled to the charging unit, the pull-up unit and the gate of the eleventh thin film transistor respectively via the pull-up node, the gate of the seventh thin film transistor is coupled to the drain of the ninth thin film transistor and the source of the eleventh thin film transistor respectively, the drain of the seventh thin film transistor is coupled to the DC low level signal input terminal;
the source of the ninth thin film transistor is coupled to the DC high level signal input terminal, the gate of the ninth thin film transistor is coupled to the fourth clock signal input terminal, the drain of the ninth thin film transistor is coupled to the gate of the sixth thin film transistor, the gate of the seventh thin film transistor and the source of the eleventh thin film transistor respectively; and
the drain of the eleventh thin film transistor is coupled to the DC low level signal input terminal.

12. A method for driving a shift register, comprising:
during a charging phase, a gate signal input terminal inputting a gate signal, a first clock signal input terminal inputting a high level, a second, a third, a fourth clock signal input terminals inputting a low level, a charging unit controlling a potential of a pull-up node as a high level and starting to charge;
during an output phase, the gate signal input terminal completing inputting, the first, the third and the fourth clock signal input terminals inputting a low level, the second clock signal input terminal inputting a high level, a pull-up unit outputting the high level signal input by the second clock signal input terminal to a gate signal output terminal;
during a reset phase, the first, the second, the fourth clock signal input terminals inputting a low level, the third clock signal input terminal inputting a high level, a pull-down unit controlling potentials of a pull-up node and the gate signal output terminal as a low level; and
during a reset maintaining phase, the first, the second, the third clock signal input terminals inputting a low level, the fourth clock signal input terminal inputting a high level, the pull-down unit continuously controlling the potentials of the pull-up node and the gate signal output terminal as a low level.

13. A gate driving device, comprising multiple stages of shift registers according to claim 1;
except for the last stage of shift registers, each gate signal output terminal of remaining stages of shift registers is coupled to a gate signal input terminal of the next stage of shift registers.

14. A display device, comprising the gate driving device according to claim 13.
